(19) United States
(12) Patent Application Publication
(10) Pub. No.: US 2024/0194558 A1
(43) Pub. Date: Jun. 13, 2024

(54) HEATSINK PEDESTALS FOR THERMAL INTERFACE MATERIAL FILL

(71) Applicant: INTERNATIONAL BUSINESS MACHINES CORPORATION, Armonk, NY (US)

(72) Inventors: Brent William Yardley, Hillsboro, OR (US); Theron Lee Lewis, Rochester, MN (US); James D. Bielick, Pine Island, MN (US); Curtis Eugene Larsen, Eden Valley, MN (US); Karl Stathakis, Owatonna, MN (US)

(21) Appl. No.: 18/065,365

(22) Filed: Dec. 13, 2022

(51) Int. Cl. H01L 23/367; H01L 21/48

(52) U.S. Cl. CPC H01L 23/367; H01L 21/4882; H01L 24/29

(57) ABSTRACT

Mounting a heat sink to an electrical component by applying a thermal interface material on at least one of a surface of one of the electrical component and the heat sink, wherein the heat sink includes a heat pedestal including an interface surface with an apex having at least one curvature extending therethrough. The heat sink contacts the electrical component through the thermal interface material. The apex of the interface surface is an element of the heat sink closest to the electrical component. The interface surface that includes the apex and the at least one curvature cause the thermal interface material to flow during the contacting so that any space between the heat sink and the electrical component is filled with thermal interface material and is substantially free of voids.

### BACKGROUND

The present disclosure relates to gap fill materials that provide for a thermal interface between two materials or devices/components.

Heat sinks have previously been provided to dissipate heat from electrical components. The electrical component typically has a flat top surface on which the heat sink is placed. Heat produced by the electrical component is efficiently dissipated using the heat sink since the heat sinks typically have a flat surface on the bottom extending over the entire surface of and which rests on the flat top surface of the electrical component.

A gap may be present between the top surface of the electrical component and the bottom surface of the heat sink. If the gap is larger than the thermal interface characteristics can support, the cooling solution fails.

Thermal interface materials may be required to minimize the thickness of the gap between the electrical component and the heat sink. The thermal interface material may be a fill that is present between the two surfaces of the electrical component and the heat sink.

### SUMMARY

In one aspect, a heat sink is described with a pedestal having an interface surface for substantially eliminating void and air gap formation in thermal interface materials positioned between the heat sink and heat producing electrical components. In one embodiment, the heat sink includes a heat dissipating body and a pedestal in direct contact with the heat dissipating body. In one embodiment, the pedestal includes an interface surface having a single apex and a convex curvature.

In another embodiment, a heat sink is described including a pedestal having a plateau surface for the apex, wherein the pedestal has a geometry of a truncated pyramid. In one embodiment, the heat sink includes a heat dissipating body and a pedestal in direct contact with the heat dissipating body. In one embodiment, the pedestal includes an interface surface having an apex with a flat plateau geometry and a sidewall geometry that defines a truncated pyramid.

In another aspect, an electrical component is described that includes a heat producing electrical component having a nominal flat surface interface; and a heat sink including a pedestal. In some embodiments, the pedestal includes a heat sink interface surface with an apex, wherein the apex of the heat sink interface surface is the portion of the heat sink that is closest to the heat producing electrical component. In some embodiments, the electrical component also includes a thermal interface material between the nominal flat surface interface of the heat producing element and the heat sink interface of the pedestal to the heat sink.

In another aspect, a method for mounting a heat sink to an electrical component is described. In one embodiment, the method includes applying a thermal interface material on at least one of the electrical component and the heat sink. In some embodiments, the heat sink includes a heat pedestal including an interface surface with an apex. The method further includes contacting the heat sink to the electrical component through the thermal interface material. In some embodiments, the apex of the interface surface is a portion of the heat sink closest to the electrical component, wherein the interface surface including the apex cause the thermal interface material to flow during the contacting so that any space between the heat sink and the electrical component is filled with thermal interface material and is substantially free of voids.

### BRIEF DESCRIPTION OF DRAWINGS

The following detailed description, given by way of example and not intended to limit the disclosure solely thereto, will best be appreciated in conjunction with the accompanying drawings, wherein like reference numerals denote like elements and parts, in which:

FIG. 1 is a perspective view illustrating a heat sink including with a heat dissipating body that is in direct contact with a heat sink pedestal including an interface surface having an apex with a single curvature extending therethrough, in accordance with one embodiment of the present disclosure.

FIG. 2 is perspective view of illustrating a heat sink including with a heat dissipating body that is in direct contact with a heat sink pedestal including an interface surface having an apex with multiple curvatures extending therethrough, in accordance with another embodiment of the present disclosure.

FIG. 3 is perspective view of illustrating a heat sink including with a heat dissipating body that is in direct contact with a heat sink pedestal that includes an interface surface having an apex with a flat plateau geometry and a sidewall geometry that defines a truncated pyramid, in accordance with another embodiment of the present disclosure.

FIG. 4 is a side cross-sectional view illustrating engagement of a heat sink with a pedestal having an interface surface with at least one curvature and a single engaging point, wherein engagement of the pedestal to the heat producing electrical element induces a laminar flow in the thermal interface material fill between the pedestal and the heat producing electrical element to avoid the formation of voids and air gaps.

### DETAILED DESCRIPTION OF THE PREFERRED EMBODIMENTS

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. For purposes of the description hereinafter, the terms “upper”, “lower”, “right”, “left”, “vertical”, “horizontal”, “top”, “bottom”, and derivatives thereof shall relate to the embodiments of the disclosure, as it is oriented in the drawing figures. The terms “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

A “thermal interface material” (shortened to TIM) is any material that is inserted between two components in order to enhance the thermal coupling between them. A common use is heat dissipation, in which the TIM is inserted between a heat-producing device (e.g., an integrated circuit) and a heat-dissipating device (e.g. a heat sink). At each interface, a thermal boundary resistance exists to impede heat dissipation. In addition, the electronic performance and device lifetime can degrade dramatically under continuous overheating and large thermal stress at the interfaces. Thermal interface materials minimize the thermal boundary resistance between layers and enhance thermal management performance. Thermal interface materials can also provide low thermal stress between materials of different thermal expansion coefficients, low elastic modulus or viscosity, flexibility, and reusability.

Examples of thermal interface materials can include thermal paste, thermal adhesives, thermal gap fill, phase change materials and metal thermal interface materials.

Thermal interface materials are often applied as a fill material to fill the space separating a heat producing electrical component and a heat sink component. It has been determined that a number of deficiencies can occur when using a fill material between two flat surfaces, e.g., the flat interface surfaces of a heat producing electrical component and a heat sink component. For example, it has been determined that when using gap filling materials between two flat surfaces that air gap, e.g., voids, can form between the elements being joined. For thermal interface fill materials, in some scenarios the voids cannot be removed, e.g., the voids can not be forced out from the center of the interface surfaces. Further, when release agents are introduced, these agents can get trapped, e.g., trapped in the airgap/void, and not be allowed to flow away from the interface. Once the structure is cured, e.g., the thermal interface material (filler) is cured, the resultant structure includes the air gaps and tracks with voids (voided racetracks). It has been determined that the presence of these air gaps and voids can result in a poor interface between the two surfaces. The poor interface can result in improper heat transfer, high thermal interface resistance, and an inconsistent thermal interface that reduces the effectiveness of the heatsink.

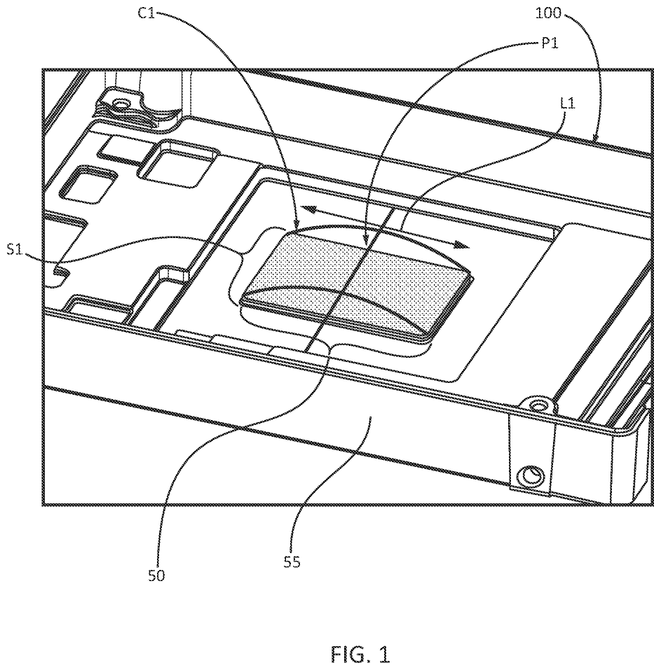

The methods and structures of the present disclosure provide a new way of designing a heatsink pedestal that is used to interface to the flat surface of a heat producing electrical component, e.g., integrated circuit (IC) chip, such as an application-specific integrated circuit (ASIC) chip. An application-specific integrated circuit is an integrated circuit (IC) chip customized for a particular use, rather than intended for general-purpose use. The interface to the heat producing electrical component may be the lidded case of an integrated circuit (IC), e.g., ASIC chip, or a lidless die. This is generally a flat surface. As will be described in further detail below, the interface surface of the pedestal provided by the designs disclosed herein has a curved surface that encourages enhanced laminar flow of the fill material, e.g., the thermal interface material. The structures and methods of the present disclosure are now described with greater detail with reference to FIGS. 1-4.

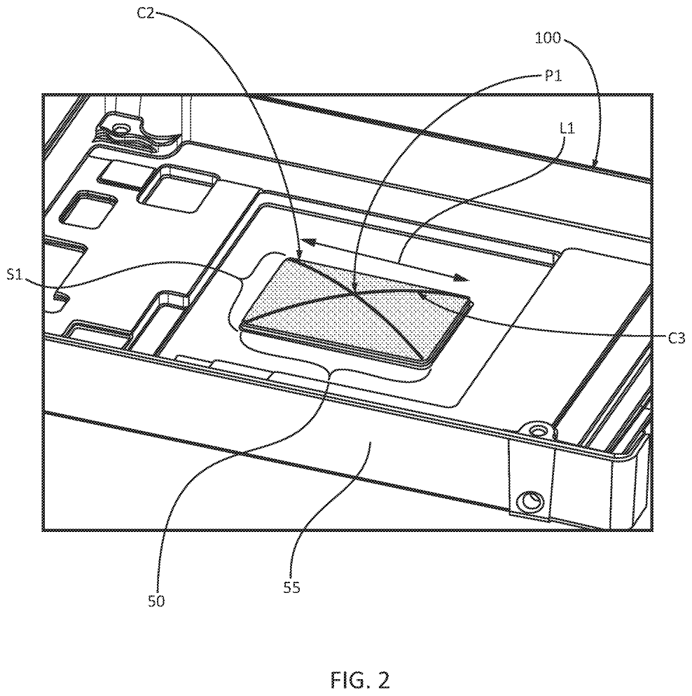

FIGS. 1 and 2 illustrate two embodiments of a heat sink 100 including a heat dissipating body 55 that is in direct contact with a heat sink pedestal 50 including a single peak P1 as opposed to being a nominal flat surface. The body 55 provides the point of the majority of heat dissipation. For example, the geometry of the body 55 may be selected to provide for increased surface area as an exchange with the atmosphere for dissipating heat, e.g., in order to dissipate heat away from electrical component that is engaged to the body via contact through the pedestal 50. In the embodiment that is depicted in FIGS. 1 and 2, the body 55 is the lid of an integrated circuit assembly, such as an application specific integrated circuit (ASIC). Although not depicted in FIGS. 1 and 2, the body 55 may include a plurality of fins 38 that can provide the surfaces for exchanging heat with the atmosphere. The pedestal 50 extends from the body of the heat sink 100, and provides for thermal communication between the body 55 and the heat generating electrical component (not shown). The source of heat generation can be an integrated circuit (IC) chip. The heat is transmitted by conduction to the package, lead frame, die attach pads, and the printed circuit board. As will be described in further detail below there may be space between the pedestal and the heat generating component. This space may be created by changes in the dimensions of the heat generating component that may result from thermal expansion. The space between the heat generating electrical component and the pedestal 50 may be filled with a thermal interface material, which provides for thermal communication between the pedestal 50 and the heat generating electrical component. The pedestal 50 of heat sink 100 is illustrated as being arranged in a center portion of body 55. It is noted that this represents only one example of the present disclosure, and it is not intended that the present disclosure be limited to only this example.

In some embodiments of the present disclosure, the body 55 and pedestal 50 of heat sink 100 may be made of various grades of aluminum Such as cast aluminum or extruded aluminum. According to embodiments of the present invention, body 34 and pedestal 36 of heatsink 100 may be made of any material, particularly materials which provide good heat dissipation.

Referring to FIGS. 1 and 2, the pedestal 50 may include a curvature at top of the pedestal of the heat sink, which provides the interface surface to the heat generating electrical component. For example, when a space is present between the pedestal 50 and the heat generating electrical component, the space is filled with a thermal interface material.

Thermal interface materials have been used to join a semiconductor package and a heat Sink, and to dissipate the heat from the semiconductor devices, such as microprocessors. Thermal interface material (TIM) may comprises a polymer matrix and a thermally conductive filler. Thermal interface material (TIM) used for electronic packages may include epoxies, greases, gels and phase change materials. Metal filled epoxies commonly are highly conductive materials that thermally cure into highly crosslinked material. Thermal greases offer good wetting and ability to conform to the interfaces, no post-dispense processing, and high bulk thermal conductivity.

Gels for thermal interface materials may comprise a cross-linkable silicone polymer, Such as Vinyl-terminated Silicone polymer, a crosslinker, and a thermally conductive filler. Gels combine the properties of both greases and crosslinked TIMs. Before cure, these materials have properties similar to grease. After cure, gels are crosslinked filled polymers, and the crosslinking reaction provides cohesive strength to circumvent the pump-out issues exhibited by greases during temperature cycling.

The thermal interface material may be thermal paste, thermal adhesive, thermal gap filler, a phase change material, a metal thermal interface material or combination thereof. Thermal paste may be composed of a base matrix and containing a thermally conductive filler. In some embodiments, the matrix materials for a thermal paste may include epoxies, silicones, urethanes, and acrylates. In some embodiments, the fillers for thermal paste can include carbon micro-particles, aluminum oxide, boron nitride, zinc oxide, and aluminum nitride.

The thermal paste can provide a thin bond line, and therefore a small thermal resistance. In some embodiments, the thermal paste has no mechanical strength (other than the surface tension of the paste and the resulting adhesive effect) and will need an external mechanical fixation mechanism. In some embodiments, thermal paste does not cure, and because it does not cure, it is used where the material can be contained or in thin application where the viscosity of the paste will allow it to stay in position during use.

Thermal adhesive is a type of thermally conductive glue used for electronic components and heat sinks. It can be available as a paste. The glue may be employed as a two-part epoxy resin. The thermally conductive material can vary including metals, metal oxides, silica or ceramic microspheres.

Gap fillers are usually silicone based because silicone has many attractive properties such as surface wetting, high thermal stability, and physical inertness. However, some offerings can contain no silicone. The silicone is normally used as the binder within a gap filler system. The silicone matrix is then filled with thermally conductive fillers—BN, ZnO, and alumina. These fillers make up the functional portion of the gap filler which gives it its thermal properties.

Phase change materials take advantage of latent heat of fusion to absorb heat, but they change phase only once to allow for the material to fill up all nooks and crevices. Screen-printable formulations deliver the reliability and performance of a phase change material with the low-cost handling of thermal grease.

Metal thermal interface materials are also suitable for use with the methods and structures of the present disclosure. Metallic materials offer high thermal conductivity, as well as low thermal interface resistance. This high conductivity translates to less sensitivity to bond line thicknesses and coplanarity issues than polymeric TIMs.

As noted above, each of the aforementioned thermal interface materials when used as a fill between the heat dissipating body 55 and the pedestal 50 can suffer from airgaps and void formation. The heath sink pedestal 50 described herein as an interface surface S1 that avoids airgap and void formation. For example, to avoid airgap and void formation in thermal interface materials, the interface surface S1 may be configured to include an apex with at least one curvature extending therethrough.

In FIG. 1, the heat sink pedestal 50 includes a single surface having a curvature (e.g., single curvature identified by C1 along a length L1 or width W1 dimension of the heat sink pedestal 50. In the embodiment depicted in FIG. 1, the curvature C1 is along the length L1 of the heat sink pedestal 50. However, as noted, the curvature C1 can also be along the width W1 of the heat sink pedestal. A “curvature” a degree by which a surface deviates from a straight line, or how a curved surface deviates from a plane. A “plane” is a flat surface on which a straight line joining any two points on it would wholly lie. The curvature C1 is convex relative to the heat producing electrical component that the pedestal 50 is in thermal communication with so that an apex of the curvature C1 is the closest surface of the pedestal 50 to the beat producing electrical component. The “apex” is the highest point of the curvature, when height is measured from the heat dissipating body 55.

In the embodiment depicted in FIG. 2, a multi-surface curvature C2, C3, to create a dome from center to the sides, can be applied to provide an interface surface S1 that avoids void and/or air gap formation in the thermal interface materials that are present between the pedestal 50 of the heat sink 100, and the heat generating component 80.

This curvature allows for the center, i.e., apex, of the heatsink pedestal to make contact with the gap filling thermal interface material, which will cause laminar flow to occur starting at the center of the curve C1, C2, C3 and moving to the edges of the pedestal 50, as the pedestal 50 and the flat top surface of the heat producing electrical component are pressed together. Any number of shapes in the pedestal 50 could be created, dome, spherical, trapezoidal, etc., to optimize the spread of the gap filler, i.e., thermal interface material.

“Laminar flow” is a type of flow pattern of a fluid in which all the particles are flowing in parallel lines, opposed to turbulent flow, where the particles flow in random and chaotic directions.

The interface surface S1 of the pedestal 50 includes an interface surface S1 that has been configured to include an apex with at least one curvature extending therefrom. The interface surface S1 provides a design of heatsink pedestal 50 that is used to interface to the flat surface of a heat producing electrical component, e.g., application specific integrated circuit (ASIC), such as a lidded case, or lidless die. This would provide a surface S1 that will encourage turbulent flow between the curved C1, C2, C3 surface of the heatsink 100 and the flat surface of the device in which a gap filler is being used as a thermal interface material. The technique by which the pedestal of a heat sink 100 having the interface surface S1 configured to include an apex with at least one curvature extending therethrough provides a method to reduce the amount of thermal interface material needed to fill the gap between the pedestal 50 and the heat producing element. Further, by substantially reducing, e.g., eliminating, air gap and void formation, the methods and systems of the present disclosure allow for the use of a release agent between the two surfaces, i.e., the pedestal and the heat producing electrical component. Will allow for the machined or extruded surface to control the amount of turbulent flow that will occur in the gap filling material as the two surfaces are brought into contact.

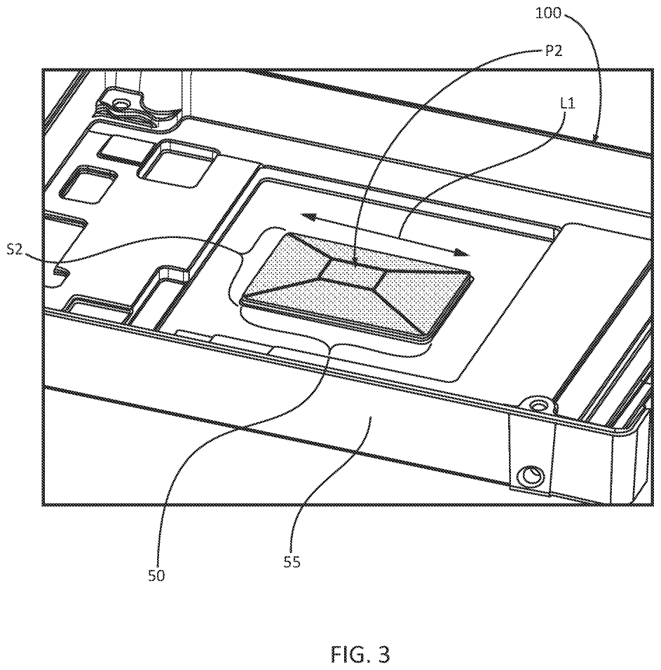

FIG. 3 illustrates another embodiment of a heat sink 100 including a heat dissipating body 55 that is in direct contact with a heat sink pedestal 50 that includes an interface surface having an apex with a flat plateau geometry P2 and a sidewall geometry (sidewalls S2) that defines a truncated pyramid. The heat sink 100 depicted in FIG. 3 can be used with a heat producing electrical component. The heat producing electrical component can have a nominal flat surface interface for engagement with the heat sink 100 having the pedestal 50 with a flat plateau geometry shaped apex P2. More particularly, the electrical component is described that includes a heat producing electrical component having a nominal flat surface interface; and a heat sink 100 including a pedestal 50. In some embodiments, the pedestal 50 includes a heat sink interface surface having an apex with flat plateau geometry P2 and a sidewall geometry S2 that defines a truncated pyramid, wherein the apex of the heat sink interface surface is the element of the heat sink that is closest to the heat producing electrical component. In some embodiments, the electrical component also includes a thermal interface material between the nominal flat surface interface of the heat producing element and the heat sink interface of the pedestal to the heat sink. The heat sink depicted in FIG. 3 may be engaged to the electrical component using a methods that includes applying a thermal interface material on at least one of the electrical component and the heat sink. The method includes contacting the heat sink to the electrical component through the thermal interface material. In some embodiments, the apex of the interface surface is an element of the heat sink 100 closest to the electrical component, wherein the interface surface including an apex with flat plateau geometry P2 and a sidewall geometry S2 that defines a truncated pyramid, which causes the thermal interface material to flow during the contacting so that any space between the heat sink 100 and the electrical component is filled with thermal interface material and is substantially free of voids. In one example, during contacting the heat sink to the electrical component, the interface surface of the pedestal including the apex with flat plateau geometry and a sidewall geometry that defines a truncated pyramid cause a laminar flow of the thermal interface material during thermal interface material pushout. It is noted that the embodiment depicted in FIG. 3 shares many elements with the embodiments described in FIGS. 1 and 2. Therefore, the elements having the same reference numbers in FIGS. 1, 2 and 3 may share the same description of those reference numbers for at least some embodiments of the present disclosure.

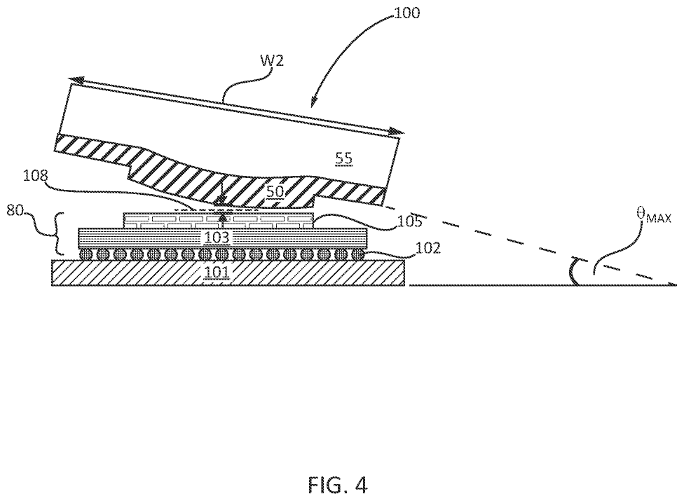

FIG. 4 illustrates how a pedestal 50 of a heat sink 100 having the interface surface S1 configured to include an apex P1 with at least one curvature C1, C2, C3 extending therethrough, e.g., curved, bowed, dome, localized raise center metal pedestal, is superior to a pedestal having a nominal flat surface, because there is a single centric/engaging point, which is provided by the apex P1 of the curvature C1, C2, C3. The single centric/engaging point of the curvature C1, C2, C3 for the pedestal 55 to the heat sink of the structures and methods for some embodiments of the present invention reduce the number of surface irregularities that affects the space/gaps that thermal interface material would fill.

FIG. 4 illustrates engagement of a heat sink 100 with a pedestal 50 having an interface surface with at least one curvature C1, C2, C3, and a single engaging point, wherein engagement of the pedestal to the heat producing electrical element 80 induces a laminar flow in the thermal interface material fill 108 between the pedestal 50 and the heat producing electrical element 80 to avoid the formation of voids and air gaps in the thermal interface material 108.

In one embodiment, the heat generating component 80 can be a semiconductor package. The semiconductor package can include a substrate 101 having a semiconductor device 103 mounted on a top surface of the substrate 101.

The semiconductor device 103 may include a semiconductor chip. The semiconductor chip may include a type IV semiconductor, such as silicon (Si), or may be a type III-V semiconductor material, such as Gallium arsenic (GaAs). Large numbers of field effect transistors (FETs), e.g., MOSFETs (metal-oxide-semiconductor field-effect transistors), can be integrate into the chip. The types of semiconductor devices, e.g., FETs, can include horizontally orientated devices, vertically orientated devices, Fin-type field effect transistors, nanowire and/or nanosheet channel type devices. Any field effect transistor (FET), e.g., a gate structure including a channel separating source and drain region, may be integrated into the chip. The above examples of FET types is provided for illustrative purposes only, and is not intended to be limiting.

In one embodiment, the substrate 101 is a printed circuit board (PCB). In another embodiment, the substrate 101 may be a different material, such as silicon (Si) or ceramic.

The semiconductor device 103 is mechanically and electrically coupled to the top surface of the substrate 101 via a plurality of solder bump connections 102. In some embodiments, the gap may be filled with an epoxy underfill material (not shown). The substrate 101 contains at least one wiring layer (not shown) that electrically connects the device to pins or balls located along the bottom surface of the substrate 101. The solder balls 102 are placed in an array and are commonly referred to as a ball grid array. Because the semiconductor device 103 is flipped into place so the solder balls 102 electrically and mechanically connect to pads or lands in the substrate 101, the semiconductor device 103 is sometimes referred to as a flip chip.

Still referring to FIG. 4, a heat spreader 105 is thermally coupled to the major surface of the flip chip structure 103 that does not carry solder balls 102 through another heat-transfer medium 104, e.g., which may be a thermal interface material similar to the thermal interface material that is engaged by the pedestal 50. The heat sink 100 is attached to the heat spreader 105 at another thermal interface using a thermal interface material 108. Thermal interface materials typically include a polymer matrix and a thermally conductive filler, and encompass several classes of materials such as epoxies, greases, gels and phase change materials, as described above with reference to FIGS. 1,2 and 3.

The heat sink 100 including the pedestal 50 allows for the more rapid dissipation of heat due to increased surface area for cooling.

Still referring to FIG. 4, the interface surface S1 of the pedestal 55 that is configured to include an apex P1 with at least one curvature C1, C2, C3 extending therethrough, e.g., curved, bowed, dome, localized raise center metal pedestal, provides a mechanical function to purposely push the thermal interface material (TIM) 108 out from the center of the area being merged.

In some embodiments, the method for mounting a heat sink 100 to an electrical component 80 includes applying a thermal interface material (TIM) 108 on at least one of a surface of one of the electrical component 80 and the heat sink 100, wherein the heat sink 100 includes the heat pedestal 50 including an interface surface S1 with an apex P1 having at least one curvature C1, C2, C3 extending therethrough, as illustrated in FIGS. 1 and 2. In some embodiments, the thermal interface material (TIM) 108 may be applied using a brush application, an injection application, spray application or curtain pour type application.

Referring back to FIG. 4, the method can further include contacting the heat sink 100 to the electrical component 80 through the thermal interface material 108, wherein the apex P1 of the interface surface 108 is an element of the heat sink 100 closest to the electrical component 80. By “closest to” it is meant that the apex is closest to the electrical component 80, because of the convex curvature of the interface surface S1 of the pedestal 50, in which “closest” includes direct contact between the electrical component 80 and the pedestal, as well as the minimum distance measured between a point on the curvature of the interface surface S1 normal (90 degree angle for measurement) to the nominal flat surface that provides the interface surface to the electrical component, in which the space of the minimum distance is filled with thermal interface material (TIM) 108.

As noted, the interface surface S1 of the pedestal 50 includes the apex P1 and the at least one curvature C1, C2, C3 cause the thermal interface material (TIM) 108 to flow during the contacting so that any space at the interface between the heat sink 100 and the electrical component 80 is filled with thermal interface material (TIM) 108 and is substantially free of voids. Voids include air gaps. In some examples, the method provides that the thermal interface material (TIM) 108 is entirely free of voids and air gaps.

In some embodiments, contacting the heat sink 100 to the electrical component 80 through the thermal interface material 108 includes an initial contact, i.e., at an initial contact angle Θ, when heat sink 100 is angled, i.e., the apex C1 is off center. The initial contact angle is measured by at the interface of an extension of the plane that is parallel to the nominal flat surface 80 that provides the interface surface of the electrical component 80 and the extension of the plane parallel to the width W1 of the heat sink 100. In one example, the initial contact angle Θ ranges from approximately 5 degrees to 20 degrees.

In some embodiments, after the initial contact, e.g., at the initial contact angle Θ, the heat sink 100 is rocked into its final position, e.g., the heat sink is rocked into a position at which the plane parallel to the width W1 of the heat sink 100 is parallel with the plane that is parallel to the nominal flat surface that provides the interface surface of the electrical component 80. During this movement, the curvatures C1, C2, C3 of the interface surface S1 of the pedestal 50 move the thermal interface material (TIM) to squeeze out (push out) with a laminar flow. The laminar flow eliminates the likelihood of voids and gaps forming in the thermal interface material (TIM) 108. In some embodiments, the method may further include applying a release agent to the heat sink 100 prior to contacting the heat sink 100 to the electrical component through the thermal interface material (TIM). In some embodiments, because the method avoids the formation of voids and airgaps, the method also avoids trapping release agents within voids and airgaps.

In some embodiments, the method also includes curing the thermal interface material (TIM) 108 following final positioning of the heat sink 100 relative to the electrical component 80. Curing may include the use of any heat producing device, such as furnaces and infrared heaters. The limits for cure time can range from about 15 minutes to about 120 minutes, and the limits for cure temperature can range from about 130° ° C. to about 180° C.

It is noted that the method described in FIG. 4, which specifically recites the pedestal 50 geometries for the embodiments depicted in FIGS. 1 and 2, is equally applicable for the pedestal geometry 50 of the embodiment depicted in FIG. 3. Therefore, the description of the method described in FIG. 4 is equally applicable to the embodiment that is depicted in FIG. 3. For example, the description for the heat producing electrical components described in FIG. 4 is suitable for describing applications for the heat sink depicted in FIG. 3, and the process steps described in FIG. 4 is equally applicable to the heat sink that is depicted in FIG. 3.

For example, in one embodiment, the embodiment of the head sink 100 depicted in FIG. 3 may be employed in a method for mounting a heat sink 55 to an electrical component 80 is described. In one embodiment, the method includes applying a thermal interface material 108 on at least one of the electrical component 80 and the heat sink 55. In some embodiments, the heat sink 55 includes a heat pedestal 50 including an interface surface. The method further includes contacting the heat sink 55 to the electrical component 80 through the thermal interface material 108. In some embodiments, the apex (provided by the flat plateau P2) of the interface surface is an element of the heat sink 55 closest to the electrical component 80, wherein the interface surface including an apex with flat plateau geometry P2 and a sidewall geometry S2 that defines a truncated pyramid cause the thermal interface material 108 to flow during the contacting so that any space between the heat sink 55 and the electrical component 80 is filled with thermal interface material 108 and is substantially free of voids. In one example, during contacting the heat sink 55 to the electrical component 80, the interface surface of the pedestal 50 including the apex with flat plateau geometry P2 and a sidewall geometry S2 that defines a truncated pyramid that causes a laminar flow of the thermal interface material 108 during thermal interface material pushout. Similar to the description of the methods for using the embodiments depicted in FIGS. 1 and 2, an anneal process may also be used with the heat sink depicted in FIG. 3 to cure the thermal interface material 108.

The method and structures that are described with reference to FIGS. 1-4 can be particularly beneficial to two-part thermal interface material (TIM) 108 chemistries, because the movement of the turbulent flow further mixes the chemicals to get the proper cure reaction of the thermal interface material (TIM) 108. The methods and structures described herein can reduce the requirement for special thermal interface material (TIM) 108 patterns design for this type of spreading. The methods and structures described herein provides a mechanism to remove and/or push voids away from the critical area of the stack up interfaces, using the turbulent flow of the thermal interface material (TIM) 108. The methods and structures described herein provide a displacing mechanism for loose contaminants like dust particles and/or localized debonding materials like oil away from the critical area of the stack up interfaces, using the turbulent flow of the thermal interface material (TIM) 108. The methods and structures described herein also provide a way to ensure thermal interface material (TIM) 108 squeeze out around the pedestal and device. This squeeze out of thermal interface material (TIM) 108 can provide support against shear forces that may affect the stack up in the processes/operations.

In addition to the thermal benefits, the methods and structures described herein can also provide mechanical benefits. For example, the domed pedestal avoids contact with the edges of the electrical component (e.g., avoids contact with die edges). This generally reduces cracking concerns when engaging the heat sink to the electrical component.

It is noted that the embodiment that is depicted in FIGS. 1-4 only represents one embodiment of the present disclosure. It is further noted that the method that is described with reference to FIGS. 1-4 is not intended to be limited to only the steps illustrated in the supplied figures.

It is to be understood that some aspects of the present invention have been described in terms of a given illustrative architecture; however, other architectures, structures, substrate materials and process features and steps can be varied within the scope of aspects of the present invention.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

While the methods and structures for heatsink pedestals for thermal interface material fill have been particularly shown and described with respect to preferred embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

1. A heat sink comprising:
a heat dissipating body; and
a pedestal in direct contact with the heat dissipating body, the pedestal including an interface surface having a single apex and a convex curvature.

2. The heat sink of claim 1, wherein the interface surface of the pedestal has a single curvature.

3. The heat sink of claim 1, wherein the interface surface of the pedestal comprising multiple curvatures to provide a dome geometry.

4. The heat sink of claim 1, wherein the pedestal is centrally positioned on the heat dissipating body.

5. The heat sink of claim 1, wherein the heat dissipating body has a lid geometry for covering an integrated circuit.

6. The heat sink of claim 1, wherein the heat dissipating body comprises at least one fin.

7. A heat sink comprising:
a heat dissipating body; and
a pedestal in direct contact with the heat dissipating body, the pedestal including an interface surface having an apex with a flat plateau geometry and a sidewall geometry that defines a truncated pyramid.

8. The heat sink of claim 7, wherein the pedestal is centrally positioned on the heat dissipating body.

9. The heat sink of claim 7, wherein the heat dissipating body has a lid geometry for covering an integrated circuit.

10. The heat sink of claim 7, wherein the heat dissipating body comprises at least one fin.

11. An electrical component, comprising:
a heat producing electrical component having a nominal flat surface interface;
a heat sink comprising a pedestal, wherein the pedestal includes a heat sink interface surface with an apex, wherein the apex of the heat sink interface surface is a portion of the heat sink closest to the heat producing electrical component; and
a thermal interface material between the nominal flat surface interface of the heat producing element and the heat sink interface of the pedestal to the heat sink.

12. The electrical component of claim 11, wherein a space between the heat producing electrical component and the heat sink interface of the pedestal to the heat sink is filled with thermal interface material and is substantially free of voids.

13. The electrical component of claim 11, wherein the pedestal of the heat sink has sidewalls with at least one curvature extending through the apex.

14. The electrical component of claim 13, wherein the apex of the interface surface is a single peak, and the at least one curvature is a single curvature.

15. The electrical component of claim 13, wherein the apex of the interface surface is a single peak, and the at least one curvature includes a plurality of curvatures, wherein the plurality of curvatures provide an interface surface having a geometry of a dome.

16. The electrical component of claim 11, wherein the thermal interface material is selected from the group consisting of thermal paste, thermal adhesives, thermal gap fill, phase change materials, metal thermal interface materials and combinations thereof.

17. The electrical component of claim 11, wherein the apex of the interface surface has a flat plateau geometry and a sidewall geometry for the pedestal defines a truncated pyramid.

18. A method for mounting a heat sink to an electrical component comprising:
applying a thermal interface material on at least one of a surface of one of the electrical component and the heat sink, wherein the heat sink includes a heat pedestal including an interface surface with an apex; and
contacting the heat sink to the electrical component through the thermal interface material, wherein the apex of the interface surface is an element of the heat sink closest to the electrical component, wherein the interface surface including the apex cause the thermal interface material to flow during the contacting so that any space between the heat sink and the electrical component is filled with thermal interface material and is substantially free of voids.

19. The method of claim 13, wherein the heat pedestal further includes at least one curvature extending through the apex, wherein during contacting the heat sink to the electrical component, the interface surface of the pedestal including the apex and the at least one curvature cause a laminar flow of the thermal interface material during thermal interface material pushout.

20. The method of claim 19, wherein the apex of the interface surface is a single peak, and the at least one curvature is a single curvature.

21. The method of claim 19, wherein the apex of the interface surface is a single peak, and the at least one curvature includes a plurality of curvatures, wherein the plurality of curvatures provide an interface surface having a geometry of a dome.

22. The method of claim 18, further comprising applying a release agent to the heat sink prior to contacting the heat sink to the electrical component through the thermal interface material.

23. The method of claim 18, wherein the thermal interface material is selected from the group consisting of thermal paste, thermal adhesives, thermal gap fill, phase change materials, metal thermal interface materials and combinations thereof.

24. The method of claim 18, wherein the apex of the pedestal has a flat plateau geometry and the pedestal has a sidewall geometry that defines a truncated pyramid.

25. The method of claim 24, wherein during the contacting of the heat sink to the electrical component, the interface surface of the pedestal including the apex with the flat plateau geometry and the sidewall geometry that defines the truncated pyramid cause a laminar flow of the thermal interface material during thermal interface material pushout.
